(19) United States
(12) Patent Application Publication
(10) Pub. No.: US 2006/0186315 A1
(43) Pub. Date: Aug. 24, 2006

(54) Active pixel image sensors

(76) Inventors: Kany-Bok Lee, Suwon-si (KR); Jae-Seob Roh, Anyang-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/347,177

(22) Filed: Feb. 6, 2006

(30) Foreign Application Priority Data
Feb. 22, 2005 (KR) 2005-14649
May 25, 2005 (KR) 2005-44173

(51) Int. Cl. H01L 27/00

(52) U.S. Cl. 250/208.1

(57) ABSTRACT

In one aspect, an imaging device is provided which includes first and second semiconductor chips and a digital interface. The first semiconductor chip includes an active pixel sensor, a digital input/output, and a plurality of control circuits, where transistors of the active pixel sensor are all n-type or p-type transistors, and where at least one of the controls circuits operates under control of a timing signal externally input to the digital input/output. The second semiconductor chip includes a timing generator which supplies the timing signal to the digital input/output of the first semiconductor chip. The digital interface is operatively connected between the digital input/output of first semiconductor chip and the second semiconductor chip.

### BACKGROUND OF THE INVENTION

1. Field of the Invention

The present invention generally relates to the field of semiconductor devices, and more particularly, the present invention relates to image sensors having active pixel arrays.

2. Description of the Related Art

Certain types of image sensors utilize photo conversion elements, such as photodiodes, to capture incident light and convert the light to an electric charge capable of image processing. Examples include Charge Coupled Device (CCD) image sensors and Complimentary Metal Oxide Semiconductor (CMOS) image sensors (CIS). The CCD image sensor is generally configured by an array of photo-detectors that are electrically connected to vertical CCDs functioning as analog shift registers. The vertical CCDs feed a horizontal CCD which in turn drives an output amplifier. In contrast, the CIS device is typically characterized by an array of photo detectors have access devices (e.g., transistors) for connection to word lines and bit lines. The word lines are connected to a row decoder circuit, and the bit lines are connected to a column decoder circuit through column amplifiers which drive an output amplifier.

Particularly when compared to the CCD image device, the manufacture of the control circuitry associated with CIS devices is considered to be more readily adaptable to CMOS fabrication techniques. As such, CIS devices have recently gained in popularity.

Nevertheless, CMOS fabrication techniques are not well suited to the formation of the active pixel array of CIS devices. Accordingly, all or part of the control circuitry of the CIS devices may be formed on a chip which is separate from the chip containing the active pixel array, with analog type signaling circuits providing communication between the two chips. Such analog interfaces, however, are prone to signal degradation and noise induced errors.

### SUMMARY OF THE INVENTION

According to one aspect of the invention, a semiconductor imaging chip is provided which includes a chip substrate, and an active pixel sensor, a digital input/output, and a plurality of control circuits located on the chip substrate. Transistors of the active pixel array are all n-type or p-type transistors, and at least one of the controls circuits operates under control of a timing signal externally input to the digital input/output.

According to another aspect of the invention, an imaging device is provided which includes first and second semiconductor chips and a digital interface. The first semiconductor chip includes an active pixel sensor, a digital input/output, and a plurality of control circuits, where transistors of the active pixel sensor are all n-type or p-type transistors, and where at least one of the controls circuits operates under control of a timing signal externally input to the digital input/output. The second semiconductor chip includes a timing generator which supplies the timing signal to the digital input/output of the first semiconductor chip. The digital interface is operatively connected between the digital input/output of first semiconductor chip and the second semiconductor chip.

According to still another aspect of the invention, an image sensor device is provided which includes first and second semiconductor chips and a digital interface. The first semiconductor chip includes image sensing circuitry, where the image sensing circuitry includes an active sensor array and an analog-to-digital converter, and where transistors of the active sensor array and the analog-to-digital converter are all of a same conductivity type. The second semiconductor chip includes image signal processing circuitry. The digital interface electrically connects the first semiconductor chip to the second semiconductor chip.

According to yet another aspect of the invention, an image sensor device is provided which includes first and second semiconductor chips operatively connected by a digital interface. The first semiconductor chip includes an active sensor array and controls circuits for outputting imaging signals via the digital interface to the second semiconductor chip. The second semiconductor chip includes image processing circuits for outputting control signals via the digital interface to the first semiconductor chip.

### BRIEF DESCRIPTION OF THE DRAWINGS

The above and other aspects and features of the present invention will become readily apparent from the detailed description that follows, with reference to the accompanying drawings, in which:

FIG. 1 is a schematic block diagram of a CMOS image sensor (CIS) according to an embodiment of the present invention;

FIG. 2 is a schematic circuit diagram of a CIS imaging chip according to an embodiment of the present invention;

FIG. 3 is a timing diagram for explaining an operation of the CIS imaging chip shown in FIG. 2 according to an embodiment of the present invention;

FIGS. 4 and 5 is are circuit diagrams of exemplary active unit pixels according to embodiments of the present invention;

FIG. 6 is a schematic cross-sectional view of a portion of an active unit pixel and MOS circuits according to an embodiment of the present invention;

FIG. 7 is a schematic block diagram of a CIS image sensor according to another embodiment of the present invention; and

FIG. 8 is a schematic block diagram of an electronic appliance which includes a CIS image sensor according to an embodiment of the present invention.

### DETAILED DESCRIPTION OF PREFERRED EMBODIMENTS

The present invention will now be described by way of several preferred but non-limiting embodiments.

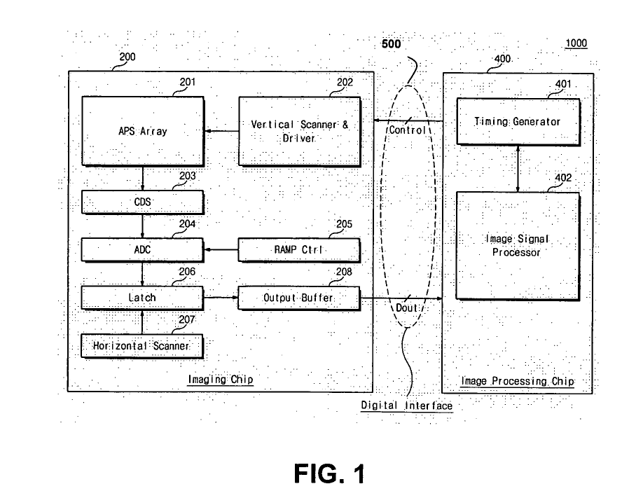

FIG. 1 is a schematic block diagram of an image sensor 1000 according to an embodiment of the present invention. As illustrated, the image sensor 1000 of this example includes first and second semiconductor chips 200 and 400 operatively coupled by a digital interface 500. The first chip 200 is an imaging chip which includes image sensors and related control circuits, while the second chip 400 is an image processing chip which generally includes image signal processing and timing circuits. Although the invention is not so limited, the chips 200 and 400 can be mounted side-by-side, or stacked one over the other, on a printed circuit board (PCB) or the like.

Still referring to FIG. 1, the imaging chip 200 of this embodiment includes active pixel sensor (APS) array 201, a vertical scan/drive circuit 202, a correlated double sampling (CDS) circuit 203, an analog-to-digital converter (ADC) 204, a ramp control circuit 205, a latch circuit 206, a horizontal scanner 207, and an output buffer 208.

The image processing chip 400 of this embodiment includes an image signal processor (ISP) 402 and a timing generator 401. As will be explained in more detail later, digital control signals are transmitted over the digital interface 500 from the image processing chip 400 to the imaging chip 200, and digital output signals (Dout) are transmitted over the digital interface 500 from the imaging chip 200 to the image processing chip 400.

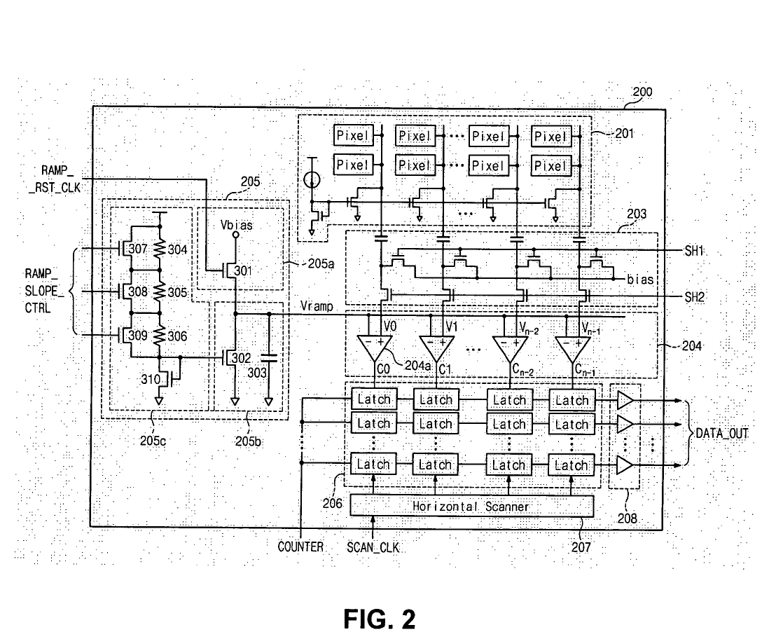

A more detailed example of the imaging chip 200 of FIG. 1 is illustrated in FIG. 2. Like reference numbers denote like elements in FIGS. 1 and 2.

Referring to FIG. 2, the APS array 201 is generally made up of an array of active unit pixels (Pixels) arranged in rows and columns. The rows of active pixels are connected to row lines (e.g., word lines) of the array 201, and the columns are connected to column lines (e.g., bit lines) of the array 201. FIG. 2 also generally illustrates a pre-charge circuit and a number of pre-charge transistors connected to each bit line of the APS array 201.

It is noted that the vertical scanner and driver 202 of FIG. 1 is not illustrated in FIG. 2 to avoid illustrating unnecessary complexities in FIG. 2. As one skilled in the art will readily appreciate, the vertical scanner and driver 202 is responsive to vertical scan control signals to drive row lines of the APS array 201 illustrated in FIG. 2.

The CDS circuit 203 is connected to column lines of the APS array 201 and operates under control of digital control signals SH1 and SH2. Operation of the CDS circuit 203 is well understood by those skilled in the art. Briefly, however, the illustrated transistors having gates connected to the control signal SH1 function to bias the bit lines, while the illustrated transistors having gates connected to the control signal SH1 function to select the row lines during a read operation of the APS array 201.

A ramp voltage Vramp is supplied by the RAMP control circuit 205. As shown in FIG. 2, the RAMP control circuit 205 is generally composed of a reset block 205a, a ramp voltage generator 205b, and a slope controller 205c.

The reset block 205a of the ramp control circuit 205 includes a transistor 301 and is responsive to a ramp reset clock signal RAMP_RST_CLK to reset the ramp voltage to a bias voltage Vbias.

The slope controller 205c includes a string of resistors 304, 305 and 306, respective bypass transistors 307, 308 and 309, and a diode-connected transistor 310. A ramp slope control signal RAMP_SLOPE_CTRL is applied to the gates of the bypass transistors 307-309 to set the level of a gate voltage that is applied to the slope generator 205b.

The gate voltage set by the slope controller 205c is applied to the gate of a transistor 302 of the ramp voltage generator 205b. As shown in FIG. 2, the transistor 302 functions to bypass a capacitive element 303, where the bypass resistance is dependent on the gate voltage applied to the transistor 302. In this manner, the discharge slope of the ramp voltage Vramp can be controlled.

The ADC 204 is generally composed of a plurality of comparators 204a. Each comparator 204a compares a row line voltage (V0-Vₙ₋₁) with the ramp voltage Vramp so as to output a comparison signal (C0-Cₙ₋₁). Each comparison signal C0-Cₙ₋₁ is either HIGH or LOW depending on whether the respective row line voltage V0-Vₙ₋₁ is less than or greater than the ramp voltage Vramp.

Still referring to FIG. 2, a counter signal COUNTER and the comparison signals C0-Cn−1 are applied to respective latch circuits (Latch) contained in the latch block 206. The latch block 206 operates as a shift register under control of the horizontal scanner 207, the timing of which is controlled by a scanning clock signal SCAN_CLK. The data generated by the latch block 206 is temporarily stored in the buffer block 208, and then output as output data DATA_OUT.

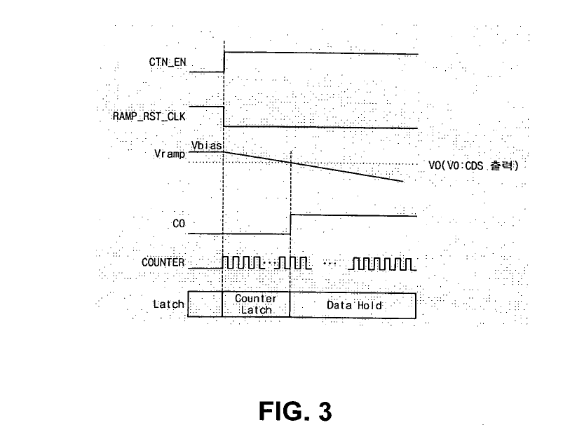

Attention is now directed to the timing diagram of FIG. 3 for a further explanation of the manner in which the ramp control circuit 205 and ADC 204 are used to read the row line voltages of the active pixel senor array 201. For simplicity, FIG. 3 is directed to the operation associated with the first row line of the APS array 201 which is connected to the first comparator 204a of the ADC 204.

Prior to activation of a control enable signal CTN_EN (not shown in FIG. 2), the ramp reset clock signal RAMP_RST_CLK is HIGH. As such, the transistor 301 of the reset circuit 205a is ON, and the ramp voltage Vramp is the bias voltage Vbias. The control enable signal CTN_EN is then activated, the ramp reset clock signal RAMP_RST_CLK becomes LOW, and the counter signal COUNTER is activated. Transistor 301 is therefore turned OFF, and the ramp voltage Vramp drops at a slope corresponding to the discharge rate defined by the capacitive element 303 and the transistor 302. The output of the comparator 204a becomes HIGH when the ramp voltage Vramp falls below the bit line voltage V0, at which time the counter latch data is held. As one skilled in the art will appreciate, the counter value is thus representative of the bit line voltage V0.

Referring again to FIG. 1, the various control and clock signals described above are supplied over the digital interface 500 from the image processing chip 400.

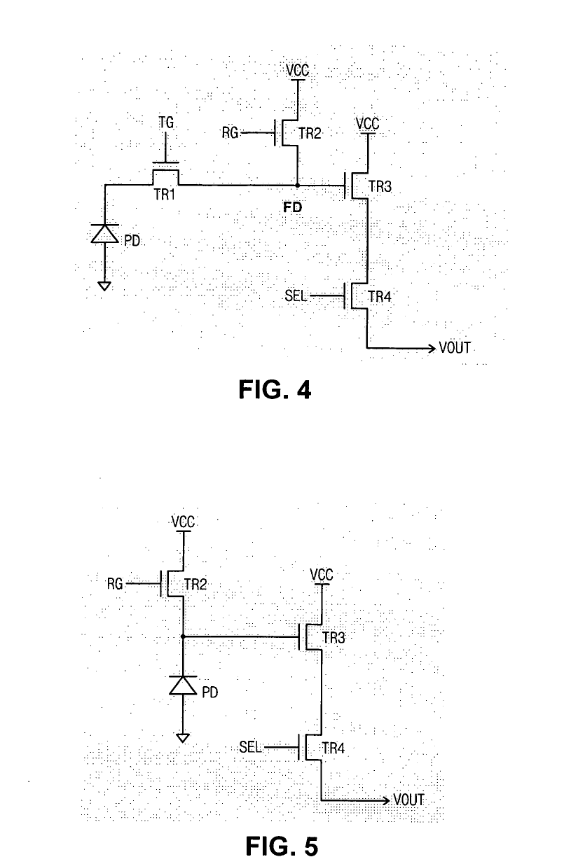

FIG. 4 illustrates an equivalent circuit diagram of one example of an active pixel (Pixel) shown in FIG. 2. A photodiode PD of the active pixel captures incident light and converts the captured light into an electric charge. The electric charge is selectively transferred from the photodiode PD to a floating diffusion region FD via a transfer transistor TR1. The transfer transistor TR1 is controlled by a transfer gate signal TG. The floating diffusion region FD is connected to the gate of a driver transistor TR3 which functions as is a source follower (amplifier) for buffering an output voltage. The output voltage is selectively transferred to an output line VOUT (i.e., a row line of the APS array 201 of FIG. 2) by a select transistor TR4. The select transistor TR4 is controlled by a select signal SEL. A reset transistor TR2 is controlled by a reset signal RG and resets charges accumulated in the floating diffusion region FD to a reference level (e.g., VCC).

FIG. 5 illustrates an equivalent circuit diagram of another example of an active pixel (Pixel) shown in FIG. 2. In this case, the electric charge from the photodiode PD is applied directly to the gate of a drive transistor TR3. As with the example of FIG. 4, the output voltage is selectively transferred to an output line VOUT by a select transistor TR4 under control of a select signal SEL. Also like the example of FIG. 4, the reset transistor TR2 is controlled by a reset signal RG to reset charges accumulated at the photodiode PD to a reference level (e.g., VCC).

The four (4) transistor circuit of FIG. 4 and the three (3) transistor circuit of FIG. 5 do not represent all possible configurations of active pixels which may be adopted in the embodiments of the present invention. The invention is not limited to the exemplary active pixel structures shown herein, and other configurations (e.g., five (5) transistor configurations) may be utilized.

As described above, electrical communication between the imaging chip 200 and the ISP 400 is established using the digital interface 500. This is achieved in the embodiment described above by forming the CDS 203, the ramp control circuit 205, the ADC 204, the latch circuit 206, and the output buffer 208 on the same semiconductor chip 200 as the APS array 201. Analog-to-digital conversion of the output of the APA array 201 takes place on the chip 200. Therefore, digital signaling between the chips 200 and 400 can be conducted at a lower frequency than analog signaling. The embodiment is thus effective in reducing data distortion and noise problems, which allows for enhanced resolution of the CIS device.

Additionally, the devices of the active pixel sensor APS array 201 may be all n-channel type or all p-channel type devices (n-channel type is preferred from the standpoint of transistor speed). For example, in the case where each active pixel is configured as in FIG. 4, the transistors TR1-TR4 of each active pixel are all n-channel type transistors or all p-channel type transistors across the entire APS array 201. Likewise, in the case where each active pixel is configured as in FIG. 5, the transistors TR2-TR4 of each active pixel are all n-channel type transistors or all p-channel type transistors across the entire APS array 201. CMOS fabrication is not ideally suited to the formation of the APS array 201. As such, manufacturing of the CIS is made more flexible by configuring the entire APS array 201 of all n-channel or all p-channel devices.

Optionally, the entirety of the chip 200 may be formed with all n-channel or all p-channel type devices, thus further enhancing the flexibility of the manufacturing processes.

In the meantime, the image processing chip 400 may be formed by conventional CMOS technology.

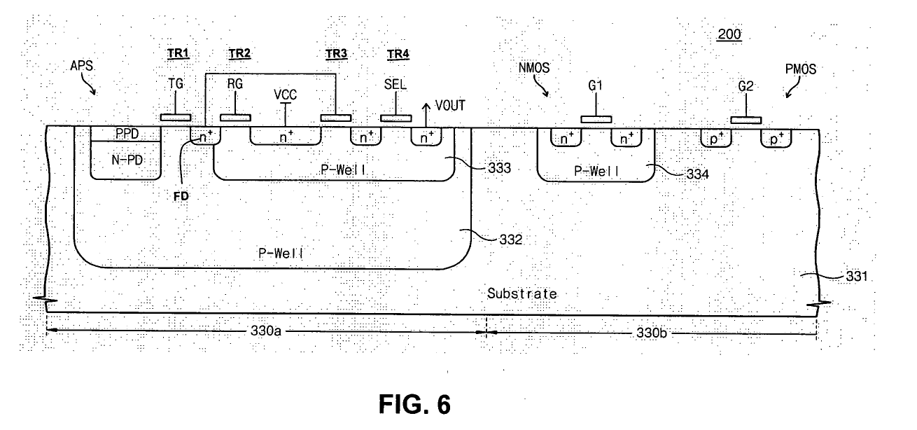

FIG. 6 is a cross-sectional schematic view of a portion of an image sensing chip in the case where the transistors of each active pixel are all n-channel type transistors.

Referring to FIG. 6, the imaging chip 200 of the illustrated example includes an n-type substrate 331 containing an active pixel sensor (APS) region 330a and a peripheral circuit region 330b. The APS region 330a contains the APS array 201 of the imaging chip 200 of FIG. 2, while the peripheral circuit region contains other elements of the imaging chip of FIG. 2. For example, the peripheral circuit region 330b may contain the CDS 203, the ADC 204 and/or the ramp control circuit 205 of FIG. 2.

FIG. 6 illustrates a portion of the active pixel of previously described FIG. 4. As shown, the active pixel is substantially contained in a first p-type well 332 of the APS region 330a. Referring collectively to FIGS. 4 and 6, the photodetector PD is configured by an n-type photodiode region N-PD located below a p-type pinning layer PPD in the first p-type well 332. Negative charges accumulate in the n-type photodiode region N-PD when light is incident on the surface of the substrate 331.

An n-type floating diffusion FD is located between the gate of the transfer transistor TR1 and the gate of the reset transistor TR2. In addition, the floating diffusion region FD is electrically connected to the gate of the drive transistor TR3. The drive transistor TR3 and the selection transistor TR4 are connected in series between VCC and VOUT. Also, as shown, the channels of reset transistor TR2, the drive transistor TR3 and the select transistor TR4 are located in a second p-well 333 formed within the first p-well 332. Generally, the second p-well 333 has a higher impurity concentration than the first p-well 332.

For illustration purposes, FIG. 6 shows an NMOS transistor receiving a gate signal G1 and a PMOS transistor receiving a gate signal G2. The NMOS transistor and PMOS transistor are both located in the peripheral circuit region 330b, and the NMOS transistor is formed in a p-well 334 of the n-type substrate 331.

As mentioned previously, the peripheral circuit region 330b may include CMOS circuits such as represented in FIG. 6. Alternately, as also mentioned above, the entirety of the imaging chip may be formed with all n-channel or all p-channel type devices. In this case, the peripheral circuit region 330b is formed of all n-channel or all p-channel type devices.

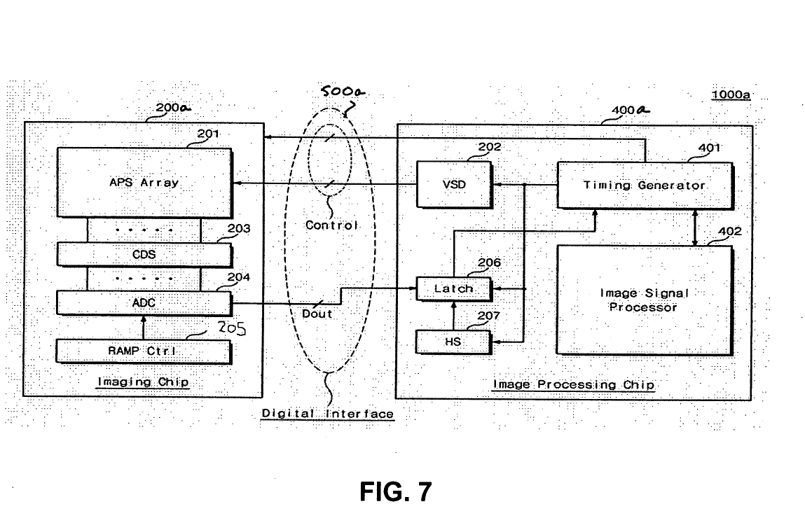

FIG. 7 is a schematic block diagram of an image sensor 1000a according to another embodiment of the present invention. As illustrated, the image sensor 1000a of this example includes first and second semiconductor chips 200a and 400a operatively coupled by a digital interface 500a. The first chip 200a is an imaging chip which includes image sensors and related control circuits, while the second chip 400a is an image processing chip which generally includes image signal processing and timing circuits. Although the invention is not so limited, the chips 200a and 400a can be mounted side-by-side, or stacked one over the other, on a printed circuit board (PCB) or the like.

Still referring to FIG. 7, the imaging chip 200a of this embodiment includes active pixel sensor (APS) array 201, a correlated double sampling (CDS) circuit 203, an analog-to-digital converter (ADC) 204, and a ramp control circuit 205.

The image processing chip 400a of this embodiment includes an image signal processor (ISP) 402, a timing generator 401, a vertical scan/drive (VSD) circuit 202, a latch circuit 206, a horizontal scanner (HS) 207. As with the embodiment of FIG. 1, digital control signals are transmitted over the digital interface 500a from the image processing chip 400a to the imaging chip 200, and digital output signals (Dout) are transmitted over the digital interface 500 from the imaging chip 200a to the image processing chip 400a. However, the embodiment of FIG. 7 differs from that of FIG. 1 in that the vertical scan/drive (VSD) circuit 202, the latch circuit 206, and the horizontal scanner (HS) 207 are equipped on the image processing chip 400a (rather than the imaging chip 200a). Since the operation of the embodiment of FIG. 7 is generally the same as that of previously described FIG. 1, a detailed operational description of FIG. 7 is omitted here to avoid redundancy.

Electrical communication between the imaging chip 200a and the ISP 400a is established using the digital interface 500a. As with the embodiment of FIG. 1, analog-to-digital conversion of the output of the APS array 201 takes place on the chip 200a. Therefore, digital signaling between the chips 200a and 400a can be conducted at a lower frequency than analog signaling. The embodiment is thus effective in reducing data distortion and noise problems, which allows for enhanced resolution of the CIS device.

As with the embodiment of FIG. 1, the devices of the active pixel sensor APS array 201 may be all n-channel type or all p-channel type devices (n-channel type is preferred from the standpoint of transistor speed). As such, manufacturing of the CIS is made more flexible by configuring the entire APS array 201 of all n-channel or all p-channel devices.

Optionally, the entirety of the chip 200a may be formed with all n-channel or all p-channel type devices, thus further enhancing the flexibility of the manufacturing processes.

In the meantime, the image processing chip 400a may be formed by conventional CMOS technology.

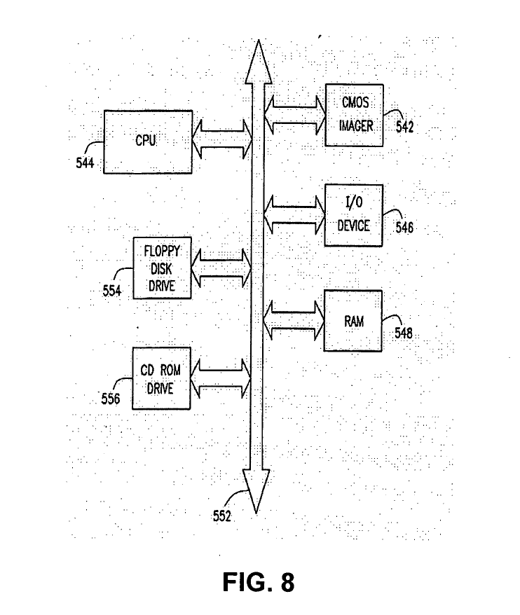

FIG. 8 illustrates an exemplary processor-based system having a CMOS imager device 542, where the CMOS imager device 542 includes an image sensor containing active unit pixels in accordance with the above-described embodiments of the present invention. The processor-based system is exemplary of a system receiving the output of a CMOS imager device. Without being limiting, such a system could include a computer system, camera system, scanner, machine vision system, vehicle navigation system, video phone, surveillance system, auto focus system, star tracker system, motion detection system, image stabilization system, mobile phone, all of which can utilize the present invention.

Referring to FIG. 8, the processor-based system of this example generally includes a central processing unit (CPU) 544, for example, a microprocessor, that communicates with an input/output (I/O) device 546 over a bus 552. The CMOS imager device 542 produces an output image from signals supplied from an active pixel array of an image sensor, and also communicates with the system over bus 552 or other communication link. The system may also include random access memory (RAM) 548, and, in the case of a computer system may include peripheral devices such as a flash-memory card slot 554 and a display 556 which also communicate with the CPU 544 over the bus 552. It may also be desirable to integrate the processor 544, CMOS imager device 542 and memory 548 on a single integrated circuit (IC) chip.

Although the present invention has been described above in connection with the preferred embodiments thereof, the present invention is not so limited. Rather, various changes to and modifications of the preferred embodiments will become readily apparent to those of ordinary skill in the art. Accordingly, the present invention is not limited to the preferred embodiments described above. Rather, the true spirit and scope of the invention is defined by the accompanying claims.

What is claimed is:

1. A semiconductor imaging chip comprising a chip substrate, and an active pixel sensor, a digital input/output, and a plurality of control circuits located on the chip substrate, wherein transistors of the active pixel array are all n-type or p-type transistors, and wherein at least one of the controls circuits operates under control of a timing signal externally input to the digital input/output.

2. The semiconductor imaging chip of claim 1, wherein the transistors of the active pixel sensor are all n-type transistors.

3. The semiconductor imaging chip of claim 2, wherein transistors of the control circuits are all n-type transistors.

4. The semiconductor imaging chip of claim 2, wherein transistors of the control circuits include both n-type and p-type transistors.

5. The semiconductor imaging chip of claim 1, wherein the control circuits comprise an analog-to-digital converter operatively coupled between the active pixel sensor and the digital input/output.

6. The semiconductor imaging chip of claim 5, wherein the transistors of the active pixel sensor are all n-type transistors, and wherein transistors of the analog-to-digital converter are all n-type transistors.

7. The semiconductor imaging chip of claim 1, wherein the control circuits comprise:
a correlated double sampling circuit which samples voltages of the active pixel sensor;
a ramp control circuit which controls a ramp voltage;
an analog-to-digital converter which converts the voltages sampled by the correlated double sampling circuit to corresponding digital signals under control of the ramp voltage;
a horizontal scanning circuit;
a latch circuit which latches the digital signals output from the analog-to-digital converter under control of the horizontal scanning circuit; and
an output buffer which buffers an output of the latch circuit and supplies a buffered output signal to the digital input/output.

8. The semiconductor imaging chip of claim 1, wherein the control circuits comprise:
a correlated double sampling circuit which samples voltages of the active pixel sensor;
a ramp control circuit which controls a ramp voltage;
an analog-to-digital converter which converts the voltages sampled by the correlated double sampling circuit to corresponding digital signals under control of the ramp voltage, and which outputs the digital signals to the digital input/output.

9. An imaging device comprising:
a first semiconductor chip comprising an active pixel sensor, a digital input/output, and a plurality of control circuits, wherein transistors of the active pixel sensor are all n-type or p-type transistors, and wherein at least one of the controls circuits operates under control of a timing signal externally input to the digital input/output;
a second semiconductor chip comprising a timing generator which supplies the timing signal to the digital input/output of the first semiconductor chip; and
a digital interface operatively connected between the digital input/output of first semiconductor chip and the second semiconductor chip.

10. The imaging device of claim 9, wherein the transistors of the active pixel sensor are all n-type transistors.

11. The imaging device of claim 10, wherein transistors of the control circuits are all n-type transistors.

12. The imaging device of claim 10, wherein transistors of the control circuits include both n-type and p-type transistors.

13. The imaging device of claim 9, wherein the control circuits comprise an analog-to-digital converter operatively coupled between the active pixel sensor and the digital input/output.

14. The imaging device of claim 13, wherein the transistors of the active pixel sensor are all n-type transistors, and wherein transistors of the analog-to-digital converter are all n-type transistors.

15. The imaging device of claim 9, wherein the control circuits comprise:
a correlated double sampling circuit which samples voltages of the active pixel sensor;
a ramp control circuit which controls a ramp voltage;
an analog-to-digital converter which converts the voltages sampled by the correlated double sampling circuit to corresponding digital signals under control of the ramp voltage;
a horizontal scanning circuit;
a latch circuit which latches the digital signals output from the analog-to-digital converter under control of the horizontal scanning circuit; and
an output buffer which buffers an output of the latch circuit and supplies a buffered output signal to the digital input/output.

16. The imaging device of claim 9, wherein the control circuits comprise:
a correlated double sampling circuit which samples voltages of the active pixel sensor;
a ramp control circuit which controls a ramp voltage;
an analog-to-digital converter which converts the voltages sampled by the correlated double sampling circuit to corresponding digital signals under control of the ramp voltage, and which outputs the digital signals to the digital input/output.

17. The imaging device of claim 16, wherein the second semiconductor chip further comprises:
a horizontal scanning circuit;
a latch circuit which latches the digital signals output over the digital interface from the analog-to-digital converter under control of the horizontal scanning circuit

18. An image sensor device comprising:
a first semiconductor chip which includes image sensing circuitry, wherein the image sensing circuit includes an active sensor array and an analog-to-digital converter, and wherein transistors of the active sensor array and the analog-to-digital converter are all of a same conductivity type;
a second semiconductor chip which includes image signal processing circuitry; and
a digital interface which electrically connects the first semiconductor chip to the second semiconductor chip.

19. The image sensor device of claim 18, wherein the transistors of the active sensor array and the analog-to-digital converter are all n-type transistors.

20. The image sensor device of claim 19, wherein the second semiconductor chip includes a timing generator.

21. An image sensor device comprising first and second semiconductor chips operatively connected by a digital interface, the first semiconductor chip including an active sensor array and controls circuits for outputting imaging signals via the digital interface to the second semiconductor chip, and the second semiconductor chip including image processing circuits for outputting control signals via the digital interface to the first semiconductor chip.
